(19) United States
(12) Patent Application Publication
(10) Pub. No.: US 2014/0204526 A1
(43) Pub. Date: Jul. 24, 2014

(54) PORTABLE COMPUTER WITH DATA STORAGE DEVICE

(71) Applicant: HON HAI PRECISION INDUSTRY CO., LTD., New Taipei (TW)

(72) Inventor: CHIH-MING CHEN, New Taipei (TW)

(73) Assignee: HON HAI PRECISION INDUSTRY CO., LTD., New Taipei (TW)

(21) Appl. No.: 13/973,148

(22) Filed: Aug. 22, 2013

(30) Foreign Application Priority Data
Jan. 22, 2013 (TW) 102102397

(51) Int. Cl. H05K 7/14

(52) U.S. Cl. CPC H05K 7/14
USPC 361/679.33

(57) ABSTRACT

A portable computer includes a motherboard and an optical disk drive (ODD) which itself houses a USB connector. The motherboard includes a south bridge (SB) chip. The optical disk drive and the USB connector are connected to the SB chip. The USB connector mounted in the ODD is exposed at an outer surface of the portable computer for connecting to a peripheral device.

### BACKGROUND

1. Technical Field

The present disclosure relates to a portable computer with a data storage device.

2. Description of Related Art

Portable computers comprise a motherboard, a data storage device, such as an optical disk drive, and a plurality of connectors for connecting with external devices. The plurality of connectors may include at least one Universal Serial Bus (USB) connector. The data storage device is located above the motherboard. The USB connector is located above the motherboard and located beside the data storage device. Both of the data storage device and the USB connector occupy space above the motherboard, which is an unnecessary waste of space.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of an embodiment of a portable computer with a data storage device.

FIG. 2 illustrates pins of an integrated connector of the data storage device of

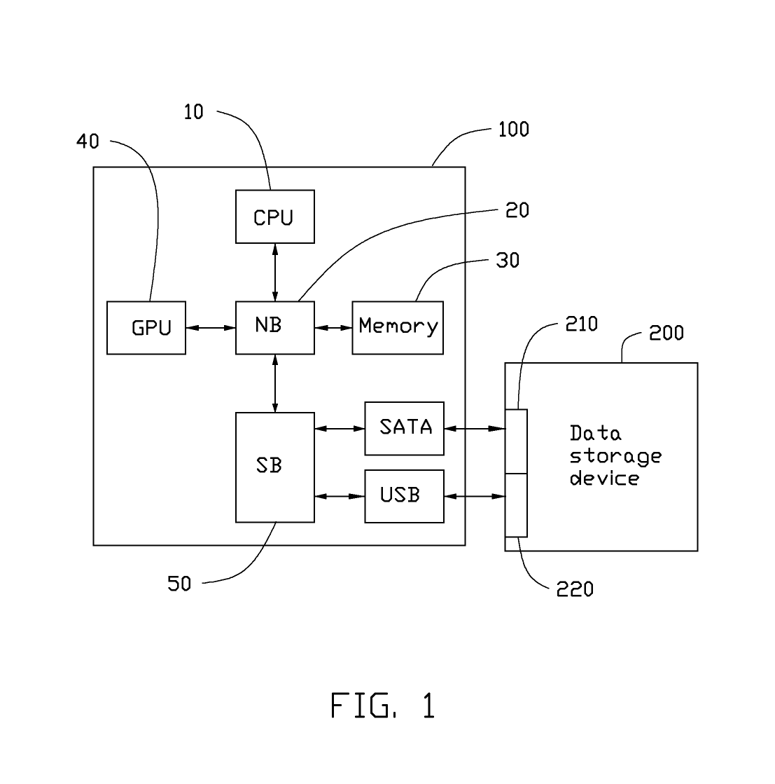

FIG. 1.

FIG. 3 illustrates a mounting position of the combination connector of FIG. 1.

### DETAILED DESCRIPTION

The disclosure is illustrated by way of example and not by way of limitation. In the figures of the accompanying drawings in which like references indicate similar elements. It should be noted that references to “an” or “one” embodiment in this disclosure are not necessarily to the same embodiment, and such references mean “at least one.”

FIG. 1 shows an embodiment of a portable computer comprising a motherboard 100 and a data storage device 200 connected to the motherboard 100. In one embodiment, the data storage device 200 is an optical disk drive (ODD).

The motherboard 100 comprises a central processing unit (CPU) 10, a north bridge (NB) chip 20 connected to the CPU 10, a memory 30 connected to the NB chip 20, a graphics processing unit (GPU) 40 connected to the NB chip 20, and a south bridge (SB) chip 50 connected to the NB chip 20.

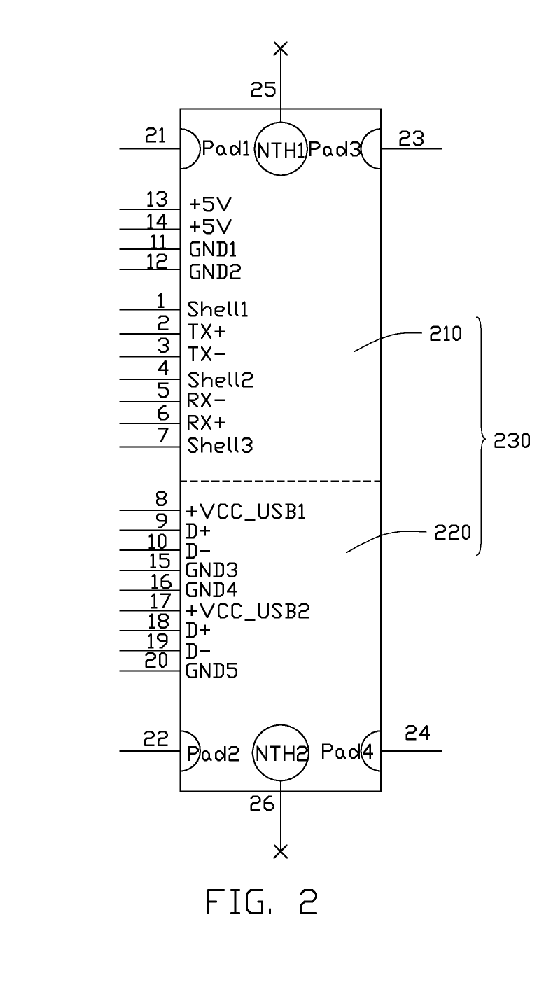

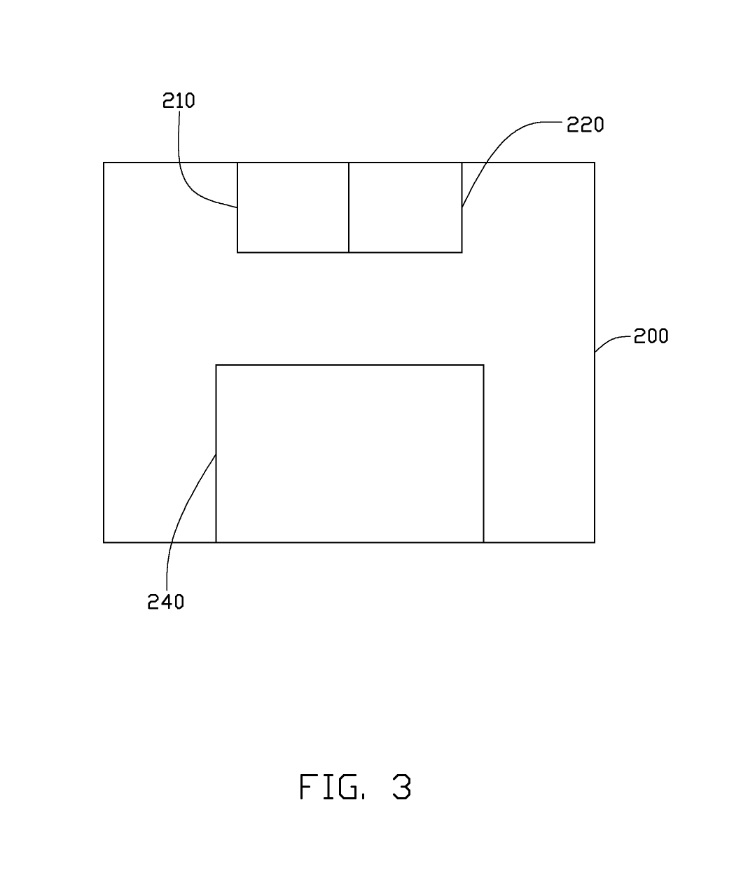

FIGS. 1 and 2 show that the data storage device 200 comprises a Serial Advanced Technology Attachment (SATA) connector 210 and a USB connector 220. The SATA connector 210 and the USB connector 220 are integrated into a combination connector 230 (see FIG. 2). The SATA connector 210 is connected to the SB chip 50 via a SATA connection. The USB connector 220 is connected to the SB chip 50 via a USB connection. The combination connector 230 can comprise twenty-six pins. The SATA connector 210 comprises pins 1 through 7 and pins 11 through 14. Pins 2 and 3 of the SATA connector 210 are used for transmitting signals. Pins 5 and 6 of the SATA connector 210 are used for receiving signals. Other pins of the SATA connector 210 are configured to connect to a power source or connect to ground. The USB connector 220 comprises pins 8 through 10 and 15 through 20. Pins 9 and 10 and Pins 18 and 19 are two pairs of data transmitting pins of the USB connector 220. Other pins of the USB connector 220 are configured to connect to the power source or connect to ground.

FIG. 3 shows an embodiment of the data storage device 200 comprising a tray 240 for mounting a floppy disk. The tray 240 is located at a front side of the data storage device 200. The combination connector 230 is mounted at a rear side of the data storage device 200. The USB connector 220 is connected to the SB chip 50 via a flexible printed circuit board (FPC).

In one embodiment, when the data storage device 200 is mounted in a chassis of the portable computer, the combination connector 230 is exposed at an outer surface of the portable computer. Since the USB connector 220 is integrated into the data storage device 200, no extra space is needed to mount the USB connector 220, saving space.

While the present disclosure has been illustrated by the description of preferred embodiments thereof, and while the preferred embodiments have been described in considerable detail, it is not intended to restrict or in any way limit the scope of the appended claims to such details. Additional advantages and modifications within the spirit and scope of the present disclosure will readily appear to those skilled in the art. Therefore, the present disclosure is not limited to the specific details and illustrative examples shown and described.

What is claimed is:

1. A portable computer comprising:
a motherboard comprising a south bridge (SB) chip;
an optical disk drive (ODD) connected to the SB chip; and
a USB connector connected to the SB chip, wherein the USB connector is mounted in the ODD and exposed at an outer surface of the portable computer for connecting a periphery USB device.

2. The portable computer of claim 1, wherein the USB connector is connected to the SB chip via a flexible printed circuit board.

3. The portable computer of claim 1, wherein the data storage device further comprises a Serial Advanced Technology Attachment (SATA) connector connected to the SB chip via a SATA connection.

4. The portable computer of claim 1, wherein the SATA connector and the USB connector are integrated into a combination connector.

5. The portable computer of claim 4, wherein the combination connector comprises a plurality of SATA pins related to the SATA connector and a plurality of USB pins related to the USB connector.

6. The portable computer of claim 5, wherein the plurality of SATA pins comprises a pair of data transmitting pins, a pair of data receiving pins, at least one power pin, and at least one ground pin.

7. The portable computer of claim 5, wherein the plurality of USB pins comprises two pairs of data transmitting pins, at least one power pin, and at least one ground pin.

8. The portable computer of claim 4, wherein the ODD comprising a tray located at a front side of the ODD for mounting a floppy disk, and the combination connector is located at a rear side of the ODD.

9. A portable computer comprising:
a motherboard comprising a south bridge (SB) chip; and
a data storage device comprising a USB connector connected to the SB chip and a Serial Advanced Technology Attachment (SATA) connector connected to the SB chip, wherein the USB connector and the SATA connector are integrated into a combination connector.

10. The portable computer of claim 9, wherein the USB connector is connected to the SB chip via a flexible printed circuit board, and the USB connector is exposed at an outer surface of the portable computer for connecting a periphery USB device.

11. The portable computer of claim 9, wherein the SATA connector is connected to the SB chip via a SATA connection, and the USB connector is connected to the south bridge chip via a USB connection.

12. The portable computer of claim 9, wherein the combination connector comprises a plurality of SATA pins related to the SATA connector and a plurality of USB pins related to the USB connector.

13. The portable computer of claim 12, wherein the plurality of SATA pins comprises a pair of data transmitting pins, a pair of data receiving pins, at least one power pin, and at least one ground pin.

14. The portable computer of claim 12, wherein the plurality of USB pins comprises two pairs of data transmitting pins, at least one power pin, and at least one ground pin.

15. The portable computer of claim 9, wherein the data storage device is an Optical Disk Drive (ODD) comprising a tray located at a front side of the ODD for mounting a floppy disk, and the combination connector is located at a rear side of the ODD.
